(19) United States
(12) Patent Application Publication
(10) Pub. No.: US 2011/0169173 A1
(43) Pub. Date: Jul. 14, 2011

(54) WIRING SUBSTRATE FOR A SEMICONDUCTOR CHIP AND SEMICONDUCOTOR PACKAGE HAVING THE WIRING SUBSTRATE

(75) Inventors: Sung-Ho MUN, Suwon-si (KR); Sun-Won Kang, Seongnam-si (KR)

(73) Assignee: Samsung Electronics Co., Ltd, Suwon-si, (KR)

(21) Appl. No.: 13/005,051

(22) Filed: Jan. 12, 2011

(30) Foreign Application Priority Data
Jan. 12, 2010 (KR) 10-2010-0002462

(51) Int. Cl. H01L 23/48

(52) U.S. Cl. 257/783; 257/782; 257/E23.01

(57) ABSTRACT

A wiring substrate for a semiconductor chip includes a substrate having a first surface and a second surface opposite to the first surface. The substrate has at least one slot from the first surface to the second surface that exposes chip pads of a semiconductor chip mounted to the first surface. The substrate has first and second regions divided by the slot. A plurality of bonding pads is arranged along both side portions of the slot and the bonding pads are connected to bonding wires that are drawn from the chip pads through the slot. First and second conductive patterns are respectively formed in the first and second regions and respectively connected to the at least one bonding pad. A merging pattern extends from the first region to the second region to electrically connect the first conductive pattern and the second conductive pattern. A merging wire electrically connects the merging pattern and the at least one chip pad.

### CROSS-REFERENCE TO RELATED APPLICATIONS

This application claims the benefit of priority under 35 U.S.C. §119 to Korean Patent Application No. 2010-2462, filed on Jan. 12, 2010 in the Korean Intellectual Property Office (KIPO), the entire contents of which are herein incorporated by reference.

### BACKGROUND

1. Field of the Invention

Example embodiments relate to a wiring substrate for a semiconductor chip and a semiconductor package having the same. More particularly, example embodiments relate to a wiring substrate for mounting a semiconductor chip thereon where conductive patterns are provided for an electrical connection to the semiconductor chip and a semiconductor package having the same.

2. Description of the Related Art

Generally, a semiconductor package may include a wiring substrate and a semiconductor chip mounted on the wiring substrate. In the semiconductor package, the semiconductor chip may be electrically connected to the wiring substrate by a plurality of bonding wires.

Recently, as the number of input/output signal lines for the semiconductor chip has increased according to the miniaturization trend of electronic products using semiconductor devices, spaces of conductive patterns for electrically connect the wiring substrate and the semiconductor chip has decreased.

In order to secure the spaces for the conductive patterns, the conductive pattern may be designed to avoid electronic components, and thus the total length of the conductive pattern may be increased to deteriorate signal transmission properties. Accordingly, a structural design for the conductive patterns of the wiring substrate is a significant issue, and further, a wiring substrate having an improved high-speed performance is required.

### SUMMARY

Example embodiments provide a wiring substrate for a semiconductor chip having improved signal transmission properties.

Example embodiments provide a semiconductor package including the wiring substrate.

Additional aspects and utilities of the present general inventive concept will be set forth in part in the description which follows and, in part, will be obvious from the description, or may be learned by practice of the present general inventive concept.

Features and/or utilities of the present general inventive concept may be realized by a wiring substrate having a first surface and a second surface opposite to the first surface, the substrate having at least one slot extending between the first surface and the second surface that exposes chip pads of a semiconductor chip adherable to the first surface, the substrate having first and second regions divided by the slot. A plurality of bonding pads is arranged along both side portions of the slot and the bonding pads are connected to bonding wires that are drawn from the chip pads through the slot. First and second conductive patterns are respectively formed in the first and second regions and may be respectively connected to the at least one bonding pad. A merging pattern extends from the first region to the second region to electrically connect the first conductive pattern and the second conductive pattern. A merging wire electrically connects the merging pattern and the at least one chip pad.

The first and second conductive patterns may be used as a power wiring for supplying power to the semiconductor chip or a ground wiring for grounding the semiconductor chip.

The wiring substrate may further include outer connection pads for connection to outer terminals, the outer connection pads respectively connected to the first and second conductive patterns.

The wiring substrate may further include a third conductive pattern that is used as a signal wiring for inputting/outputting an electrical signal to/from the semiconductor chip.

The widths of the first and second conductive patterns may be greater than the width of the third conductive pattern.

The chip pad connected to the merging wire may be electrically connected to the bonding pad by the bonding wire and the bonding pad may be electrically connected to another conductive pattern that is used as a power wiring or ground wiring.

A plurality of the slots may be formed in the substrate and the merging pattern may extend between the slots.

One slot may be formed in the substrate and the merging pattern may extend across the slot.

The wiring substrate may further include a supporting structure for supporting the merging pattern, the supporting structure being formed to extend across the slot.

Features and/or utilities of the present general inventive concept may also be realized by a semiconductor package that includes a substrate having a first surface and a second surface opposite to the first surface, the substrate having at least one slot that extends between the first and second surfaces, and the substrate having first and second regions divided by the slot. A semiconductor chip is adhered to the first surface of the substrate, and chip pads of the semiconductor chip may be exposed through the slot. A plurality of bonding pads is arranged along both side portions of the slot. A plurality of bonding wires is drawn from the chip pads through the slot to be connected to the bonding pads. First and second conductive patterns are respectively formed in the first and second regions and are respectively connected to the at least one bonding pad. A merging pattern extends from the first region to the second region to electrically connect the first conductive pattern and the second conductive pattern. A merging wire electrically connects the merging pattern and the at least one chip pad.

The first and second conductive patterns may be used as a power wiring for supplying power to the semiconductor chip or a ground wiring for grounding the semiconductor chip.

The semiconductor package may further include a third conductive pattern that is used as a signal wiring for inputting/outputting an electrical signal to/from the semiconductor chip.

The widths of the first and second conductive patterns may be greater than the width of the third conductive pattern.

The chip pad connected to the merging wire may be electrically connected to the bonding pad by the bonding wire and the bonding pad may be electrically connected to another conductive pattern that is used as a power wiring or ground wiring.

A plurality of the slots may be formed in the substrate and the merging pattern may extend between the slots.

One slot may be formed in the substrate and the merging pattern may extend across the slot.

The semiconductor package may further include a supporting structure for supporting the merging pattern, the supporting structure being formed to extend across the slot.

A wiring substrate for a semiconductor chip may include conductive patterns that are formed in first and second regions of a substrate and divided by a slot. A merging pattern may electrically connect the conductive patterns. The conductive patterns may be used as a power wiring or ground wiring. The wiring substrate may further include a merging wire for electrically connecting the merging pattern and another conductive pattern that is used as another power wiring or ground wiring.

Accordingly, the merging pattern and the merging wire may improve electrical properties of the semiconductor package such as power transmission properties and optimize design layout of the semiconductor package.

Features and/or utilities of the present general inventive concept may also be realized by a semiconductor package including a substrate having first and second surfaces substantially parallel to each other and at least one slot formed between the first and second surfaces, the first surface having bonding pads located adjacent to the slot, a semiconductor chip mounted to the second side of the substrate and having chip pads located to face the slot of the substrate, a first conductive pattern on the first surface of the substrate, the first conductive pattern connecting at least one of the bonding pads to a first outer connection pad, a merging pattern crossing the at least one slot of the substrate on the first surface and connected to the first conductive pattern, and a second conductive pattern on the first surface of the substrate to connect the merging pattern to a second outer connection pad.

The substrate may have a plurality of slots, and the merging pattern may be located between two of the plurality of slots.

The semiconductor package may further include a support located beneath the merging pattern to support the merging pattern, the support being separated from the semiconductor chip.

The semiconductor package may further include bonding wires to connect the bonding pads of the substrate to chip pads of the semiconductor chip.

Features and/or utilities of the present general inventive concept may also be realized by a computing device including a control unit to receive a command and to perform an operation according to the received command, memory to receive data from the control unit and to store data to be accessed by the control unit, and an interface unit to provide commands to the control unit. At least one of the control unit and the memory may include a semiconductor package including a substrate having first and second surfaces substantially parallel to each other and at least one slot formed between the first and second surfaces, the first surface having bonding pads located adjacent to the slot, a semiconductor chip mounted to the second side of the substrate and having chip pads located to face the slot of the substrate, and bonding wires extending through the slot to connect the chip pads of the semiconductor chip with the bonding pads of the substrate.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

The above and/or other aspects of the present general inventive concept will become apparent and more readily appreciated from the following description of the exemplary embodiments, taken in conjunction with the accompanying drawings, in which:

FIG. 1 is a plan view illustrating a semiconductor package including a wiring substrate for a semiconductor chip in accordance with an example embodiment.

FIG. 2 is an enlarged plan view illustrating a portion of the semiconductor package of FIG. 1

FIG. 3 is a cross-sectional view taken along the line III-III′ in FIG. 2.

FIG. 4 is a cross-sectional view taken along the line IV-IV′ in FIG. 1.

FIG. 5 is a plan view illustrating a semiconductor package including a wiring substrate for a semiconductor chip in accordance with another example embodiment.

FIG. 6 is an enlarged plan view illustrating a portion of the semiconductor package of FIG. 5.

FIG. 7 is a cross-sectional view taken along the line VII-VII′ in FIG. 6.

FIG. 8A is a plan view illustrating a portion of a semiconductor package including only first and second conductive patterns that are formed in first and second regions respectively.

FIG. 8B is a plan view illustrating a portion of a semiconductor package further including a merging pattern.

FIG. 8C is a plan view illustrating a portion of a semiconductor package further including a merging pattern and a merging wire.

FIG. 9 is a block diagram of a computing device according to an embodiment of the present general inventive concept.

### DETAILED DESCRIPTION OF THE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

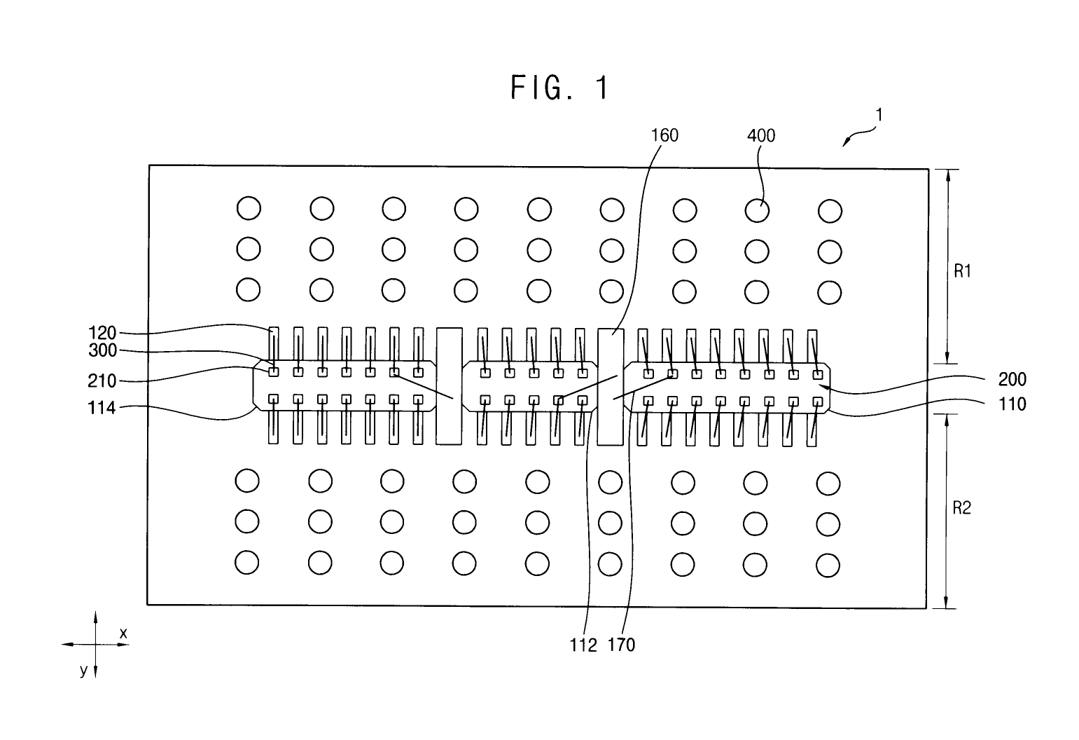

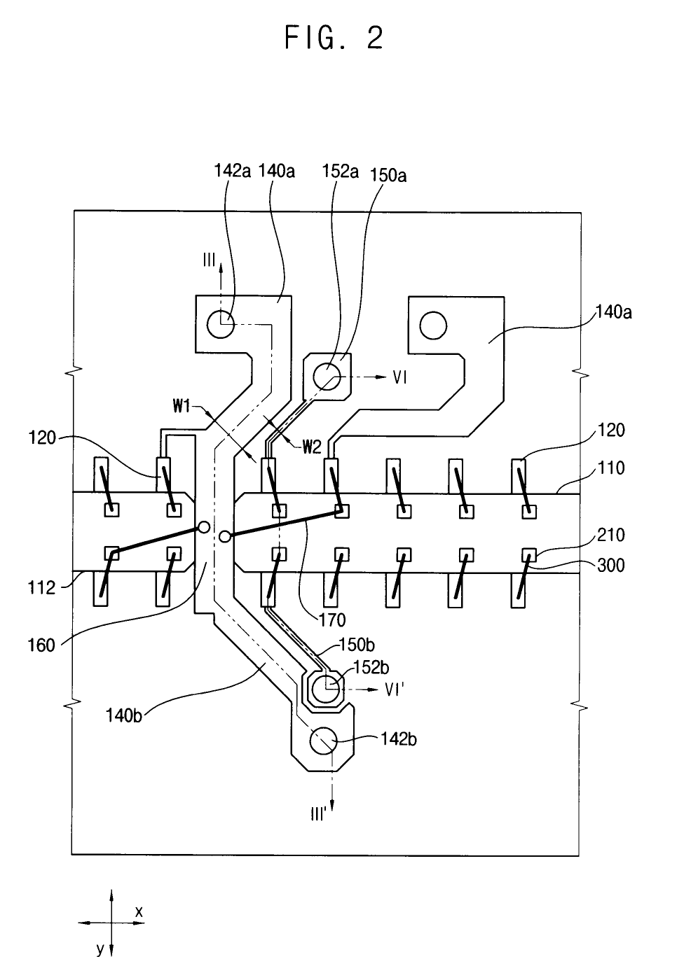

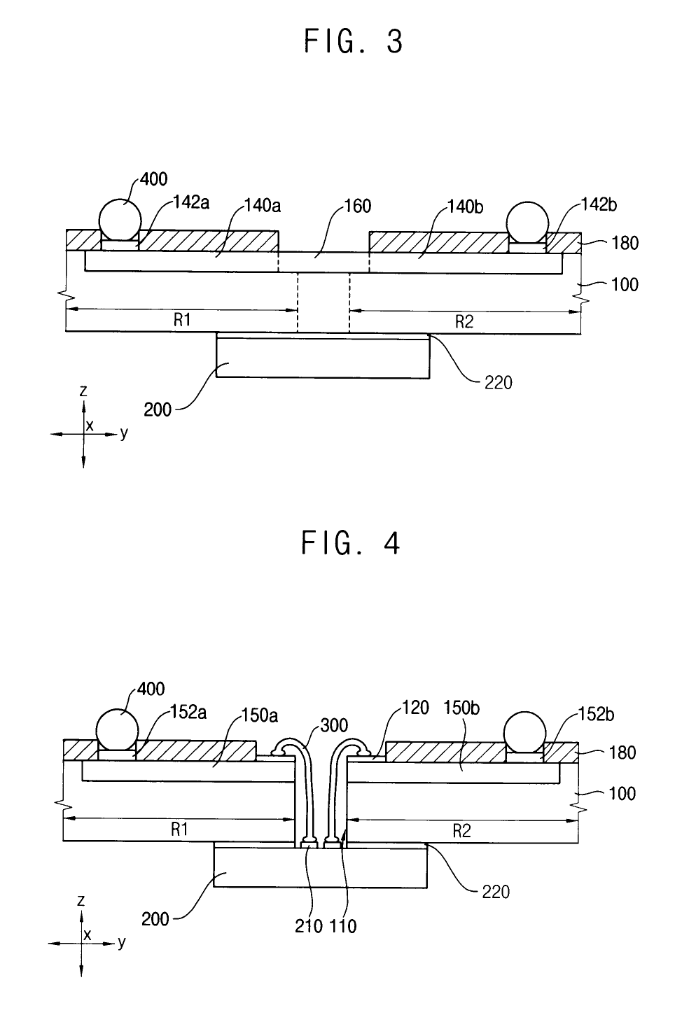

FIG. 1 is a plan view illustrating a semiconductor package 1 including a wiring substrate for a semiconductor chip 200 in accordance with an example embodiment. FIG. 2 is an enlarged plan view illustrating a portion of the semiconductor package 1 of FIG. 1. FIG. 3 is a cross-sectional view taken along the line III-III′ in FIG. 2. FIG. 4 is a cross-sectional view taken along the line IV-IV′ in FIG. 1.

Referring to FIGS. 1 to 4, a semiconductor package 1 in accordance with an example embodiment includes a wiring substrate, a semiconductor chip 200 mounted on the wiring substrate, and a plurality of bonding wires 300 electrically connecting the semiconductor chip 200 to the wiring substrate.

In an example embodiment, the wiring substrate may include a substrate 100 having first and second surfaces opposite to each other, a plurality of conductive patterns 140a, 140b, 150a, 150b formed on the first surface of the substrate, and a plurality of bonding pads 120 respectively connected the conductive patterns 140a, 140b, 150a, 150b. For example, the wiring substrate may be a printed circuit board (PCB). The PCB may include a multi-layered circuit board having various circuits therein.

At least one slot 110, 112, 114 may be formed in the middle region of the substrate 110. The slot may penetrate the substrate 100. For example, the slot may have a rectangular shape. Accordingly, the slot may be formed to extend along a first direction. The slot may provide a space for the bonding wires to extend through.

The sizes, locations and number of the slots formed in the substrate may be determined based on the semiconductor chip mounted on the substrate. For example, when the semiconductor chip is mounted on the middle region of the substrate 100, the slot may be formed in the middle region of the substrate 100.

In an example embodiment, three slots 110, 112, 114 may be serially arranged in the middle region of the substrate. However, the number of the slots may be not limited thereto. Accordingly, the substrate 100 may have a first region R1 and a second region R2 divided by the slots. The first and second regions R1, R2 may be defined to be spaced apart from each other by the slots being interposed between the first and second regions R1, R2.

The semiconductor chip 200 may be mounted on the second surface of the substrate 100. The semiconductor chip 200 may be adhered to the substrate 100 via an adhesive film 220. A plurality of the chip pads 210 may be formed on an active surface of the semiconductor chip 200. The chip pads 210 of the semiconductor chip 200 may be exposed through the slot. Although it is not illustrated in the figures, at least one semiconductor chip may be additionally formed on the semiconductor chip 200.

In an example embodiment, the semiconductor chip 200 may include a plurality of the circuit elements. The circuit element may include a plurality of memory devices. Examples of the memory devices may be a volatile memory device and a non-volatile memory device. Examples of the volatile memory device may be DRAM, SRAM, etc. Examples of the non-volatile memory device may be EPROM, EEPROM, Flash EEPROM, etc.

A plurality of the bonding pads 120 may be arranged along side portions of the slots 110, 112, 114 on the first surface of the substrate 110. The bonding pads 120 may be connected to the chip pads 210 of the semiconductor chip 200 by the bonding wires 300, respectively. The bonding wires 300 may be drawn from the chip pads 210 of the semiconductor chip 200 through the slot to be connected to the bonding pads 120 on the substrate 110.

A plurality of the conductive patterns 140a, 140b, 150a, 150b may be formed on the first surface of the substrate 100. The conductive patterns 140a, 140b, 150a, 150b may be formed on the first and second regions R1, R2, respectively. The conductive pattern may have a planar shape.

In an example embodiment, outer connection pads 142a, 142b, 152a, 152b for connection to outer terminals may be formed on the first surface of the substrate 100. An insulation layer 180 may be formed on the first surface of the substrate 100 to expose the outer connection pads 142a, 142b, 152a, 152b. For example, the insulation layer 180 may include solder resist.

An outer connection member such as a solder ball may be disposed on the outer connection pads 142a, 142b, 152a, 152b exposed by the insulation layer 180. The semiconductor package may be mounted on a module substrate (not illustrated) via the solder balls to provide a memory module (not illustrated).

In an example embodiment, the first conductive pattern 140a may be formed on the first region R1. A first end portion of the first conductive pattern 140a may be electrically connected to the bonding pad 120. A second end portion of the first conductive pattern 140a may be electrically connected to the outer connection pad 142a.

The second conductive pattern 140b may be formed on the second region R2. A first end portion of the second conductive pattern 140b may be electrically connected to the bonding pad 120. A second end portion of the second conductive pattern 140b may be electrically connected to the outer connection pad 142b.

The third conductive patterns 150a, 150b may be formed on the first and second regions R1, R2, respectively. First end portions of the third conductive patterns 150a, 150b may be electrically connected to the bonding pads 120, respectively. Second end portions of the third conductive patterns 150a, 150b may be electrically connected to the outer connection pads 152a, 152b, respectively.

In an example embodiment, the first and second conductive patterns 140a, 140b may be used as a power wiring for supplying power to the semiconductor chip 200 or a ground wiring for grounding the semiconductor chip 200. The third conductive patterns 150a, 150b may be used as a signal wiring for inputting/outputting an electrical signal to/from the semiconductor chip 200.

In this case, a width (W1) of the first conductive pattern 140a may be greater than a width (W2) of the third conductive pattern 150a. The first and second conductive patterns used as a power wiring or ground wiring may have a width greater than that of the third conductive pattern used as a signal wiring.

As illustrated in FIG. 2, in an example embodiment, a merging pattern 160 may be formed on the first surface of the substrate 100. The merging pattern 160 may extend from the first region (R1) to the second region (R2). The merging pattern 160 may extend between the slots 110 and 112, and between the slots 112 and 114. The merging pattern 160 may electrically connect the first conductive pattern 140a of the first region (R1) and the second conductive pattern 140b of the second region (R2). For example, the merging pattern 160 may have a width greater than the third conductive pattern 150a used as a signal wiring.

Accordingly, the first and second conductive patterns 140a and 140b that are respectively formed in the first and second regions R1, R2, may be merged to decrease resistances and impedances of the conductive patterns, to thereby improve electrical properties of the semiconductor package.

As illustrated in FIGS. 1-4, the top and bottom surfaces of the substrate 100 may be defined by the directions x and y and may extend horizontally. The slot 110 may extend between the top and bottom surfaces and may extend vertically in the direction z. The slot 110 may either be a contiguous slot that includes each of the portions 110, 112, and 114, or, as illustrated in FIGS. 1-4, the slots 110, 112, and 114 may be separate slots formed in the substrate 100 and separated by material, such as by portions of the substrate 100.

If the slots 110, 112, and 114 are contiguous, the merging pattern 160 spans the slots. On the other hand, as illustrated in FIG. 3, when the slots 110, 112, and 114 are separated by substrate material, the merging pattern 160 is formed on the substrate 100. The merging pattern 160 and conductive patterns 140a, 140b, 150a, and 150b may be formed on or in a surface of the substrate 100 opposite the surface on which the semiconductor chip 200 is mounted. The conductive patterns 140a, 140b, 150a, and 150b may include multiple layers that extend into the substrate 100 without contacting or breaching the surface of the substrate 100 on which the semiconductor chip 200 is mounted.

In an example embodiment, the semiconductor package may further include a merging wire 170. The merging wire 170 may electrically connect the wiring pattern 160 and at least one chip pad 210. For example, the merging wire 170 may be a bonding wire. The merging wire 170 may be drawn from the chip pad 210 of the semiconductor chip 200 through the slot to be connected to the merging pattern 160.

In this case, the chip pad 210 connected to the merging wire 170 may be electrically connected to the bonding pad 120 by the bonding wire 300. Then, the bonding pad 120 may be electrically connected to another first conductive pattern 140a that is used as another power wiring or ground wiring in the first region (R1).

Accordingly, the merging wire 170 may additionally merge the first and second conductive patterns 140a and 140b that are used as another power wiring or another ground wiring, to thereby provide free bonding layout with chip pads of the semiconductor chip, high speed performance of the semiconductor package and optimize design layout of the conductive patterns.

A first sealing member (not illustrated) may be provided in the slots 110, 112, 114 of the substrate 100 to cover the chip pads 210 of the semiconductor chip 200 and the bonding wires 300. A second sealing member (not illustrated) may be provided on the substrate 110 to cover the semiconductor chip 200. The first and second sealing members may protect the semiconductor chip 200 from the outside. For example, the first and second sealing member may include epoxy molding compound (EMC).

Ball lands 400, which may be solder balls, for example, may be formed on the outer connection pads 142b and 152b or any other connection pads on the surface of the semiconductor package 1 opposite the surface on which the semiconductor chip 200 is mounted.

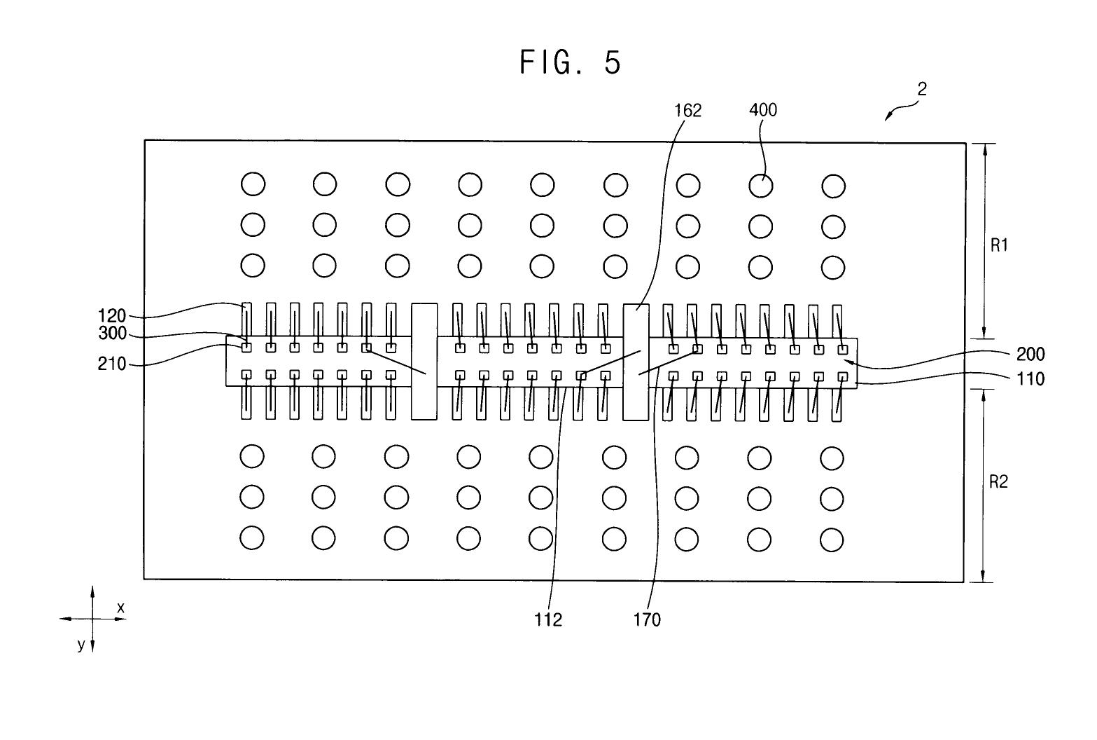

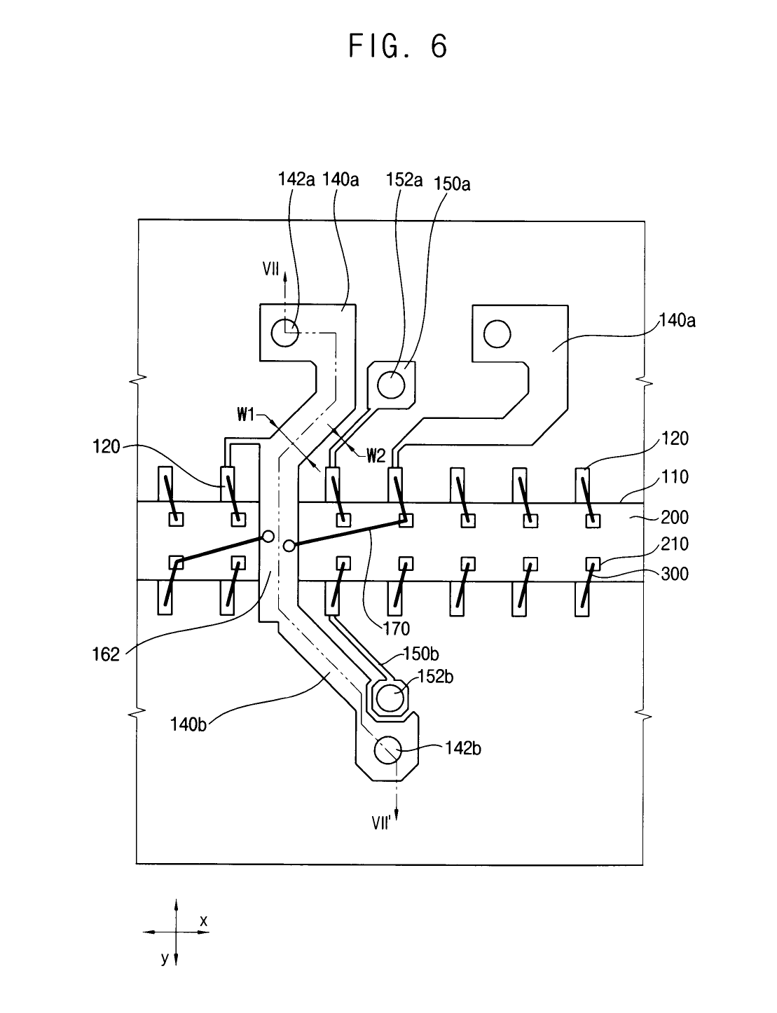

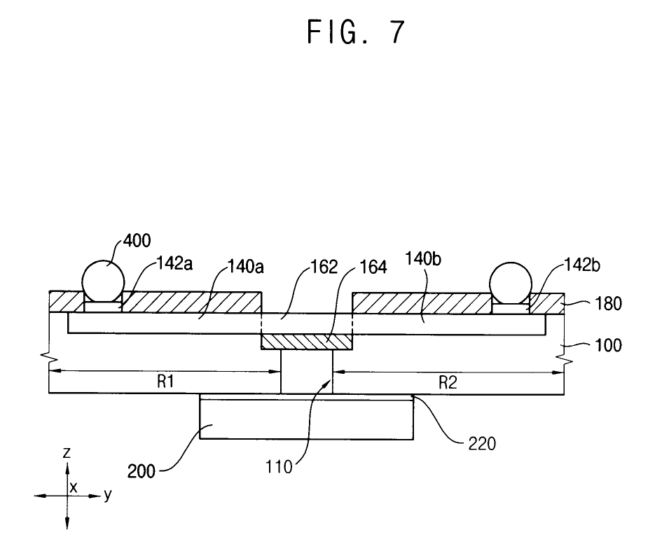

FIG. 5 is a plan view illustrating a semiconductor package including a wiring substrate for a semiconductor chip in accordance with another example embodiment. FIG. 6 is an enlarged plan view illustrating a portion of the semiconductor package of FIG. 5. FIG. 7 is a cross-sectional view taken along the line VII-VII′ in FIG. 6. The semiconductor package of the present embodiment is substantially the same as in the embodiment of FIG. 1 except a slot and a merging pattern. Thus, the same reference numerals will be used to refer to the same or like elements as those described in the embodiment of FIG. 1 and any further repetitive explanation concerning the above elements will be omitted.

Referring to FIGS. 5 to 7, a wiring substrate for a semiconductor chip in accordance with another example embodiment may include a substrate 100 having one slot 110 that penetrates the substrate 100.

In another example embodiment, the substrate 110 may have first and second surfaces opposite each other. One slot 110 may be formed in the middle region of the substrate 110. For example, the slot may have a rectangular shape. Accordingly, the slot may be formed to extend along a first direction. The slot may provide a space for the bonding wires to extend through.

Accordingly, the substrate 100 may have a first region R1 and a second region R2 divided by the slot. The first and second regions R1, R2 may be defined to be spaced apart from each other by the slot being interposed between the first and second regions R1, R2.

A plurality of the bonding pads 120 may be arranged along a side portion of the slot 110 on the first surface of the substrate 110. The bonding pads 120 may be connected to chip pads 210 of a semiconductor chip 200 by bonding wires 300, respectively. The bonding wires 300 may be drawn from the chip pads 210 of the semiconductor chip 200 through the slot to be connected to the bonding pads 120 on the substrate 110.

A first conductive pattern 140a may be formed on the first region R1. A first end portion of the first conductive pattern 140a may be electrically connected to the bonding pad 120. A second end portion of the first conductive pattern 140a may be electrically connected to the outer connection pad 142a.

A second conductive pattern 140b may be formed on the second region R2. A first end portion of the second conductive pattern 140b may be electrically connected to the bonding pad 120. A second end portion of the second conductive pattern 140b may be electrically connected to the outer connection pad 142b.

Third conductive patterns 150a, 150b may be formed on the first and second regions R1, R2, respectively. First end portions of the third conductive patterns 150a, 150b may be electrically connected to the bonding pads 120, respectively. Second end portions of the third conductive patterns 150a, 150b may be electrically connected to the outer connection pads 152a, 152b, respectively.

The first and second conductive patterns 140a, 140b may be used as a power wiring for supplying power to the semiconductor chip 200 or a ground wiring for grounding the semiconductor chip 200. The third conductive patterns 150a, 150b may be used as a signal wiring for inputting/outputting an electrical signal to/from the semiconductor chip 200.

In this case, a width (W1) of the first conductive pattern 140a may be greater than a width (W2) of the third conductive pattern 150a. The first and second conductive patterns used as a power wiring or ground wiring may have a width greater than that of the third conductive pattern used as a signal wiring.

In another example embodiment, a merging pattern 162 may be formed across the slot 110. The merging pattern 162 may be formed on a supporting structure 164. The supporting structure 164 may have a bridge shape to connect both sides of the slot 110. The supporting structure 164 may be formed using an insulating material having rigidity capable of supporting a merging wire 170 such as a bonding wire. The supporting structure 164 may be made of the same material as the substrate 100 or of a different material. The supporting structure 164 may be inserted into the slot 110 to extend from one side of the slot 110 to the other.

The merging pattern 162 may extend from the first region (R1) to the second region (R2). The merging pattern 162 may electrically connect the first conductive pattern 140a of the first region (R1) and the second conductive pattern 140b of the second region (R2).

Accordingly, the first and second conductive patterns 140a and 140b that are respectively formed in the first and second regions R1, R2, may be merged to decrease resistances and impedances of the conductive patterns, to thereby improve electrical properties of the semiconductor package.

Unlike the semiconductor package 1 of FIGS. 1-4, the semiconductor package 2 of FIGS. 5-7 includes a plurality of semiconductor chips 200 mounted adjacent to a single slot 110 on the second surface of the substrate 100. The merging pattern 162 formed on the first surface of the substrate 100 is formed on a supporting structure 164 that spans the single slot 110. The supporting structure 164 may be separated from the semiconductor chips 200 in the vertical direction z, and may further extend only part-way into the slot 110 so that the supporting structure 164 may not extend all the way to the second surface of the substrate 100.

Hereinafter, electrical properties of a semiconductor package in accordance with example embodiments will be explained.

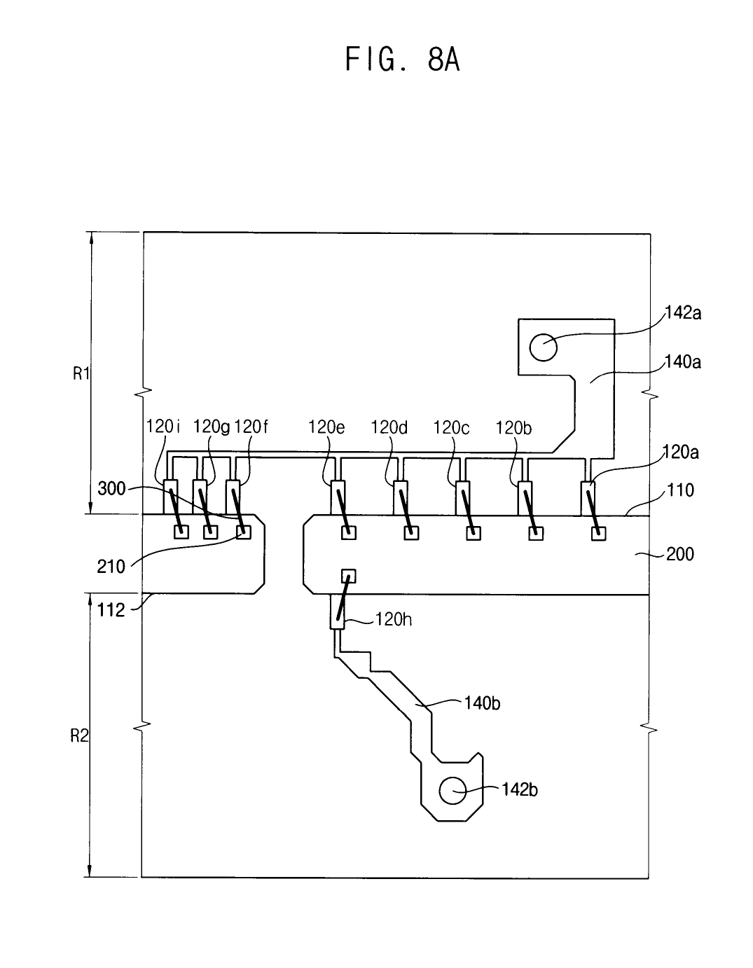

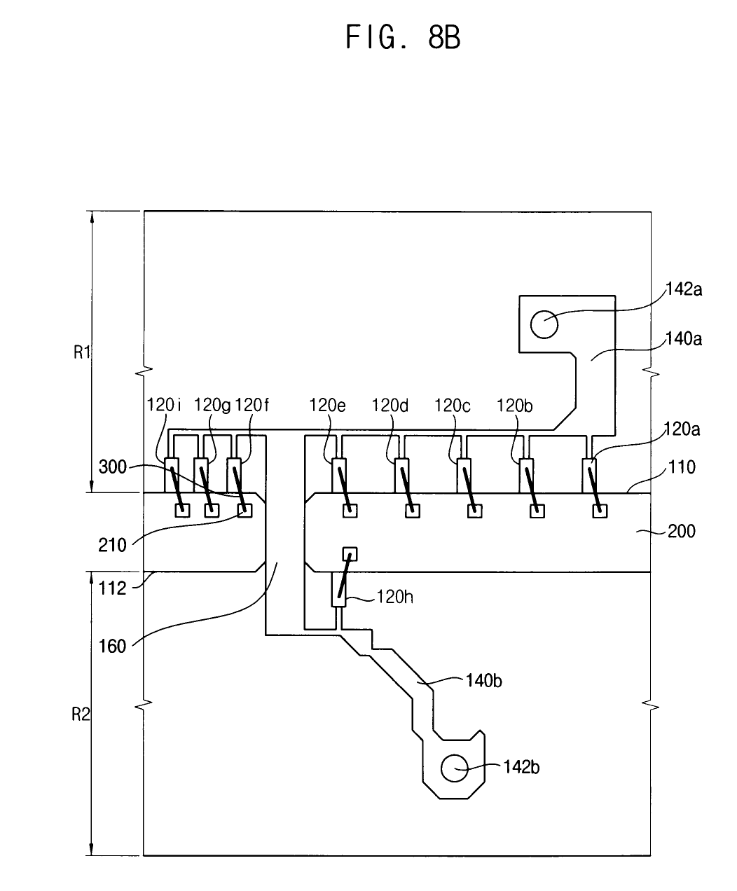

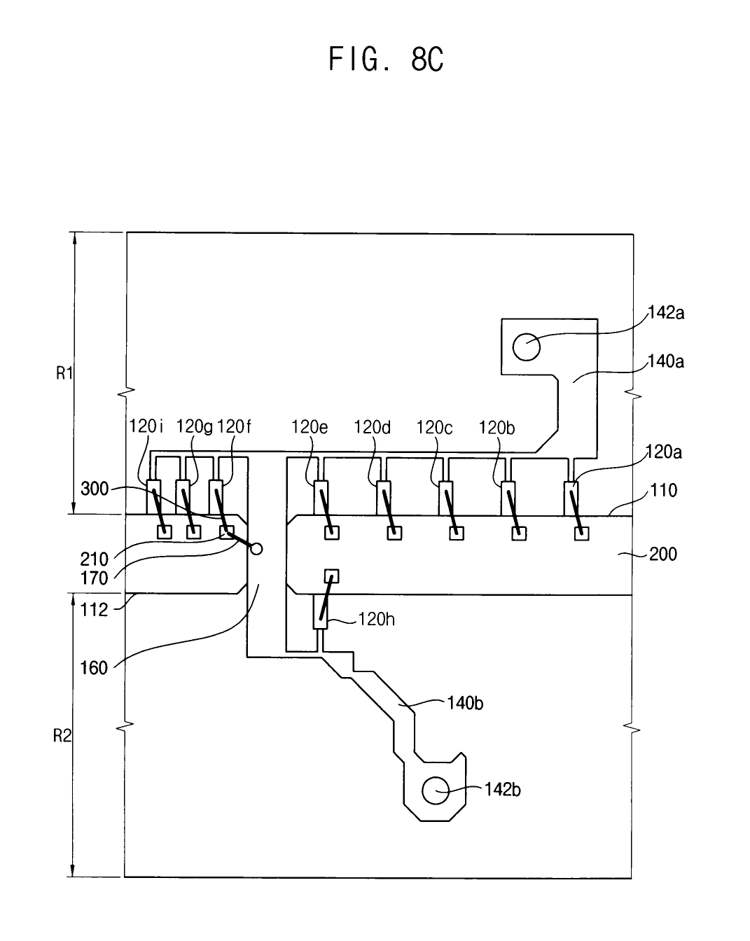

FIG. 8A is a plan view illustrating a portion of a semiconductor package including only first and second conductive patterns that are formed in first and second regions respectively. FIG. 8B is a plan view illustrating a portion of a semiconductor package further including a merging pattern. FIG. 8C is a plan view illustrating a portion of a semiconductor package further including a merging pattern and a merging wire.

Referring to FIG. 8A, the first conductive pattern 140a may be formed in the first region (R1) of the substrate 100 and the second conductive pattern 140b may be formed in the second region (R2) of the substrate 100. The first and second conductive patterns 140a, 140b may be formed in the first and second regions R1, R2 divided by the slots 110, 112.

A plurality of bonding pads 120a, 120b, 120c, 120d, 120e, 120f, 120g and 120i may be arranged along the slots in the first region (R1) of the substrate 100. The bonding pads 120a, 120b, 120c, 120d, 120e, 120f, 120g and 120i may be electrically connected to the first conductive pattern 140a. Another bonding pad 120h may be formed in the second region (R2) of the substrate 100. The bonding pad 120h may be electrically connected to the second conductive pattern 140b. The first and second conductive patterns 140a, 140b may be power wirings for supplying power to the semiconductor chip.

Table 1 represents resistances and impedances of the bonding pads of FIG. 8A obtained using computer simulation. The resistances and impedances may be obtained at a specific operating speed (3200 MHz) by a parasitic extraction software tool, Q3D Extractor.

TABLE 1

| Bonding Pad | Resistance (R, Ω) | Inductance (L, nH) |
|---|---|---|
| 120a | 0.367 | 2.164 |
| 120b | 0.373 | 2.202 |
| 120c | 0.387 | 2.305 |
| 120d | 0.432 | 2.563 |
| 120e | 0.460 | 2.682 |
| 120f | 0.509 | 3.035 |
| 120g | 0.509 | 3.728 |
| 120h | 0.656 | 4.104 |
| 120i | 0.437 | 2.166 |

Referring FIG. 8B, the first and second conductive patterns 140a, 140b may be formed in the first and second regions R1, R2 divided by the slots 110, 112. The bonding pads 120a, 120b, 120c, 120d, 120e, 120f, 120g and 120i may be formed in the first region (R1) and electrically connected to the first conductive pattern 140a. Another bonding pad 120h may be formed in the second region (R2) of the substrate 100 and electrically connected to the second conductive pattern 140b.

A merging pattern 160 may be formed to extend from the first region (R1) to the second region (R2) of the substrate 100. The merging pattern 160 may extend between the slots 110, 112. The merging pattern 160 may electrically connect the first conductive pattern 140a of the first region (R1) and the second conductive pattern 140b of the second region (R2).

Table 2 represents resistances and impedances of the bonding pads of FIG. 8B obtained using computer simulation. The resistances and impedances may be obtained at a specific operating speed (3200 MHz) by a parasitic extraction software tool, Q3D Extractor.

TABLE 2

| Bonding Pad | Resistance (R, Ω) | Inductance (L, nH) |
|---|---|---|
| 120a | 0.362 | 1.918 |
| 120b | 0.367 | 1.879 |
| 120c | 0.375 | 1.860 |
| 120d | 0.401 | 1.705 |
| 120e | 0.414 | 1.658 |
| 120f | 0.442 | 1.518 |
| 120g | 0.475 | 2.085 |
| 120h | 0.530 | 2.482 |
| 120i | 0.425 | 1.413 |

Referring to Tables 1 and 2, the resistance of the bonding pad of the semiconductor package including the merging pattern 160 may be reduced by max. 0.12652 and the inductance may be reduced by max. 1.642 nH.

Referring to FIG. 8C, the first and second conductive patterns 140a, 140b may be formed in the first and second regions R1, R2 divided by the slots 110, 112. The bonding pads 120a, 120b, 120c, 120d, 120e, 120f, 120g and 120i may be formed in the first region (R1) and electrically connected to the first conductive pattern 140a. Another bonding pad 120h may be formed in the second region (R2) of the substrate 100 and electrically connected to the second conductive pattern 140b. The merging pattern 160 may be formed to extend from the first region (R1) to the second region (R2) of the substrate 100 and extend between the slots 110, 112. The merging pattern 160 may electrically connect the first conductive pattern 140a of the first region (R1) and the second conductive pattern 140b of the second region (R2).

A merging wire 170 may electrically connect the merging pattern 160 and at least one chip 210. The chip pad 210 connected to the merging wire 170 may be electrically connected to the bonding pad 120g by the bonding wire 300.

Table 3 represents resistances and impedances of the bonding pads of FIG. 8C obtained using computer simulation. The resistances and impedances may be obtained at a specific operating speed (3200 MHz) by a parasitic extraction software tool, Q3D Extractor.

TABLE 3

| Bonding Pad | Resistance (R, Ω) | Inductance (L, nH) |
|---|---|---|
| 120a | 0.332 | 1.918 |
| 120b | 0.367 | 1.879 |
| 120c | 0.375 | 1.860 |
| 120d | 0.401 | 1.705 |
| 120e | 0.414 | 1.658 |
| 120f | 0.443 | 1.518 |
| 120g | 0.269 | 1.560 |
| 120h | 0.521 | 2.406 |
| 120i | 0.426 | 1.411 |

Referring to Tables 2 and 3, the resistance of the bonding pad of the semiconductor package including the merging pattern 160 and the merging wire 170 may be reduced by max. 0.206Ω and the inductance may be reduced by max. 1.525 nH. Accordingly, the merging pattern and the merging wire may improve electrical properties of the semiconductor package such as power transmission properties.

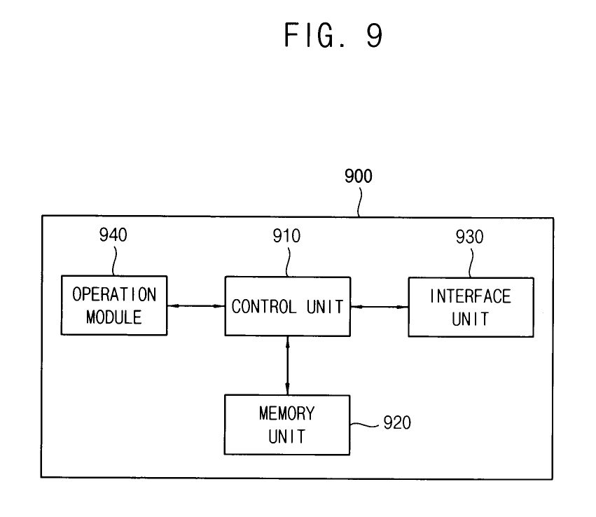

FIG. 9 illustrates a computing device 900 that includes at least one semiconductor package 1 according to the present general inventive concept. The computing device 900 may include a control unit 910 to receive and process commands, a memory unit 920 to store data, and an interface unit 930 to transmit and receive data and commands to and from the control unit 910. The control unit 910 may include, for example, a processor, logic circuitry, memory, or other support circuitry to support the control operations of the computing device 900. The memory 920 may include one or more memory devices such including volatile and non-volatile memory, RAM, ROM, magnetic or optical disks, or other memory. According to one embodiment, the memory unit 920 includes a semiconductor package 1, and the semiconductor chip 200, discussed above with respect to FIGS. 1-8, may be a memory chip that is accessed by the control unit 910.

The interface unit 930 may include one or more input terminals or ports to transmit data. For example, the interface unit 930 may include a keypad, keyboard, mouse, touch-screen, or other device to receive user input. The interface unit 930 may also include one or more electrical ports to receive data from an external electronic device and to transmit data to the external device.

The computing device 900 may also include an operation module 940 that may perform additional operations of the computing device 900. For example, the computing device 900 may be a camera or other portable device equipped with a camera, and the operation module 940 may include a lens, and/or other optical imaging circuitry. The operation module 940 may include printing or image-forming optics if the computing device 900 is an image-forming apparatus, video processing circuitry if the computing device 900 includes a display device, such as a TV, monitor, or other screen, audio processing circuitry if the device is an audio device, one or more motors if the device is motor-driven or generates a tactile operation, or any other necessary type of operational circuitry. According to an embodiment of the present general inventive concept, the operation module 940 may also include a semiconductor package 1.

As mentioned above, a wiring substrate for a semiconductor chip may include conductive patterns that are formed in first and second regions of a substrate and divided by a slot. A merging pattern may electrically connect the conductive patterns. The conductive patterns may be used as a power wiring or ground wiring. The wiring substrate may further include a merging wire for electrically connecting the merging pattern and another conductive pattern that is used as another power wiring or ground wiring.

Accordingly, the merging pattern and the merging wire may improve electrical properties of the semiconductor package such as power transmission properties and optimize design layout of the semiconductor package.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Although a few embodiments of the present general inventive concept have been shown and described, it would be appreciated by those skilled in the art that changes may be made in these embodiments without departing from the principles and spirit of the general inventive concept, the scope of which is defined in the claims and their equivalents.

What is claimed is:

1. A wiring substrate for a semiconductor chip, comprising:
a substrate having a first surface and a second surface opposite to the first surface, the substrate having at least one slot from the first surface to the second surface that exposes chip pads of a semiconductor chip adherable to the first surface, the substrate having first and second regions divided by the slot;
a plurality of bonding pads arranged along both side portions of the slot and connected to bonding wires that are drawn from the chip pads through the slot;
first and second conductive patterns respectively formed in the first and second regions and respectively connected to the at least one bonding pad;
a merging pattern extending from the first region to the second region to electrically connect the first conductive pattern and the second conductive pattern; and
a merging wire electrically connecting the merging pattern and the at least one chip pad.

2. The wiring substrate of claim 1, wherein the first and second conductive patterns are used as a power wiring for supplying power to the semiconductor chip or a ground wiring for grounding the semiconductor chip.

3. The wiring substrate of claim 2, further comprising outer connection pads for connection to outer terminals, the outer connection pads respectively connected to the first and second conductive patterns.

4. The wiring substrate of claim 2, further comprising a third conductive pattern that is used as a signal wiring for inputting/outputting an electrical signal to/from the semiconductor chip.

5. The wiring substrate of claim 4, wherein the widths of the first and second conductive patterns are greater than the width of the third conductive pattern.

6. The wiring substrate of claim 1, wherein the chip pad connected to the merging wire is electrically connected to the bonding pad by the bonding wire and the bonding pad is electrically connected to another conductive pattern that is used as a power wiring or ground wiring.

7. The wiring substrate of claim 1, wherein a plurality of the slots is formed in the substrate and the merging pattern extends between the slots.

8. The wiring substrate of claim 1, wherein one slot is formed in the substrate and the merging pattern extends across the slot.

9. The wiring substrate of claim 8, further comprising a supporting structure for supporting the merging pattern, the supporting structure being formed to extend across the slot.

10. A semiconductor package, comprising:
a substrate having a first surface and a second surface opposite to the first surface, the substrate having at least one slot, the substrate having first and second regions divided by the slot;
a semiconductor chip adhered to the first surface of the substrate, chip pads of the semiconductor chip being exposed through the slot;
a plurality of bonding pads arranged along both side portions of the slot;
a plurality of bonding wires drawn from the chip pads through the slot to be connected to the bonding pads;
first and second conductive patterns respectively formed in the first and second regions and respectively connected to the at least one bonding pad;
a merging pattern extending from the first region to the second region to electrically connect the first conductive pattern and the second conductive pattern; and
a merging wire electrically connecting the merging pattern and the at least one chip pad.

11. The semiconductor package of claim 10, wherein the first and second conductive patterns are used as a power wiring for supplying power to the semiconductor chip or a ground wiring for grounding the semiconductor chip.

12. The semiconductor package of claim 11, further comprising a third conductive pattern that is used as a signal wiring for inputting/outputting an electrical signal to/from the semiconductor chip.

13. The semiconductor package of claim 12, wherein the widths of the first and second conductive patterns are greater than the width of the third conductive pattern.

14. The semiconductor package of claim 10, wherein the chip pad connected to the merging wire is electrically connected to the bonding pad by the bonding wire and the bonding pad is electrically connected to another conductive pattern that is used as a power wiring or ground wiring.

15. The semiconductor package of claim 10, wherein a plurality of the slots is formed in the substrate and the merging pattern extends between the slots.

16. The semiconductor package of claim 10, wherein one slot is formed in the substrate and the merging pattern extends across the slot.

17. The semiconductor package of claim 16, further comprising a supporting structure for supporting the merging pattern, the supporting structure being formed to extend across the slot.

18. A semiconductor package, comprising:
a substrate having first and second surfaces substantially parallel to each other and at least one slot formed between the first and second surfaces, the first surface having bonding pads located adjacent to the slot;
a semiconductor chip mounted to the second surface of the substrate and having chip pads located to face the slot of the substrate;
a first conductive pattern on the first surface of the substrate, the first conductive pattern connecting at least one of the bonding pads to a first outer connection pad;
a merging pattern crossing the at least one slot of the substrate on the first surface, the merging pattern connected to the first conductive pattern; and
a second conductive pattern on the first surface of the substrate to connect the merging pattern to a second outer connection pad.

19. The semiconductor package according to claim 18, wherein the substrate has a plurality of slots, and
the merging pattern is located between two of the plurality of slots.

20. The semiconductor package according to claim 18, further comprising a support located beneath the merging pattern to support the merging pattern, the support being separated from the semiconductor chip.
